(19) United States
(12) Patent Application Publication
(10) Pub. No.: US 2026/0298267 A1
(43) Pub. Date: Oct. 1, 2026

(54) Pumping Device, Pumping Method, and Radiation Generator Thereof

(71) Applicant: BRIGHTEST TECHNOLOGY TAIWAN CO, LTD., Hsinchu County (TW)

(72) Inventors: WAI KWUEN CHOONG, Hsinchu County (TW); Ching-Teng Fan, Hsinchu County (TW); Shih-Cheng Liu, Hsinchu County (TW); Kuo-Feng Tseng, Santa Clara, CA (US)

(73) Assignee: BRIGHTEST TECHNOLOGY TAIWAN CO, LTD., Hsinchu county (TW)

(21) Appl. No.: 19/089,028

(22) Filed: Mar. 25, 2025

(51) Int. Cl. F04F 99/00; H05G 1/02

(52) U.S. Cl. CPC F04F 99/00; H05G 1/02

(57) ABSTRACT

A pumping device includes a first chamber; a second chamber located downstream of the first chamber, and a third chamber. The second chamber is connected between the first chamber and the third chamber. A channel structure divides the third chamber into a first compartment and a second compartment. The first compartment is enclosed between the second chamber and the second compartment. The first compartment and the second chamber are connected through an open end and at least one hole of the first compartment. The open end and the at least one hole are oriented at different angles. Pressure within the second chamber is lower than pressure within the first chamber, pressure within the first compartment, and pressure within the second compartment.

### BACKGROUND OF THE INVENTION

### 1. Field of the Invention

The present invention relates to a pumping device, a pumping method, and a radiation generator thereof, and more particularly, to a pumping device, a pumping method, and a radiation generator thereof that reduce leakage.

### 2. Description of the Prior Art

Maintaining a significant pressure difference between two areas is crucial but challenging. For example, in a differential pumping system for an XUV generating process, high efficiency (or higher photon counts) is achieved when a compartment is maintained at a pressure below 2 Torr, which is comparable to a vacuum condition with no helium gas present. However, high pressure in the compartment drives helium gas to flow toward another compartment and enter an efficiency-determining region. The flow field in the efficiency-determining region becomes unstable due to the collision of the two-flow streams from the two compartments. Consequently, as the helium pressure in the compartment rises and helium flows into the efficiency-determining region, the efficiency declines, resulting in poor performance for the XUV generator system. The issue of unstable flow conditions in differential pumping must be addressed.

### SUMMARY OF THE INVENTION

It is therefore a primary objective of the present application to provide a pumping device, a pumping method, and a radiation generator thereof, to improve over disadvantages of the prior art.

An embodiment of the present invention discloses a pumping device, comprising a first chamber; a second chamber, located downstream of the first chamber; and a third chamber, wherein the second chamber is connected between the first chamber and the third chamber; wherein a channel structure divides the third chamber into a first compartment and a second compartment; wherein the first compartment is enclosed between the second chamber and the second compartment; wherein the first compartment and the second chamber are connected through an open end and at least one hole of the first compartment; wherein the open end and the at least one hole are oriented at different angles; wherein pressure within the second chamber is lower than pressure within the first chamber, pressure within the first compartment, and pressure within the second compartment.

Another embodiment of the present invention discloses a pumping method for a pumping device, wherein the pumping device comprises a first chamber, a second chamber, and a third chamber, the second chamber is connected between the first chamber and the third chamber, and the pumping method comprising maintaining pressure within the second chamber lower than pressure within the first chamber, pressure within a first compartment of the third chamber, and pressure within a second compartment of the third chamber; and maintaining a connection between the first compartment and the second chamber through an open end and at least one hole of the first compartment; wherein a channel structure divides the third chamber into the first compartment and the second compartment; wherein the first compartment is enclosed between the second chamber and the second compartment; wherein the open end and the at least one hole are oriented at different angles.

Another embodiment of the present invention discloses a radiation generator, comprising a first chamber; a second chamber, connected to the first chamber via a first open end; and a third chamber, connected to the second chamber via a second open end; wherein input radiation is converted at least into extreme ultraviolet (XUV) radiation via at least one nonlinear process in the first chamber or between the first open end and the second open end; wherein a channel structure divides the third chamber into a first compartment and a second compartment; wherein the first compartment and the second chamber are connected through an open end and at least one hole of the first compartment; wherein the open end and the at least one hole are oriented at different angles.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 4 are schematic diagrams of devices according to embodiments of the present invention.

FIG. 5 is a schematic diagram of a device according to an embodiment of the present invention.

FIG. 6 illustrates a simulation of flow streams of the non-solid substances in the device shown in FIG. 5.

FIG. 7 and FIG. 8 are schematic diagrams of devices according to embodiments of the present invention.

FIG. 9 illustrates a simulation of flow streams of the non-solid substances in the device shown in FIG. 8.

FIG. 10 illustrates a simulation of flow streams of the non-solid substances under different pressure conditions.

### DETAILED DESCRIPTION

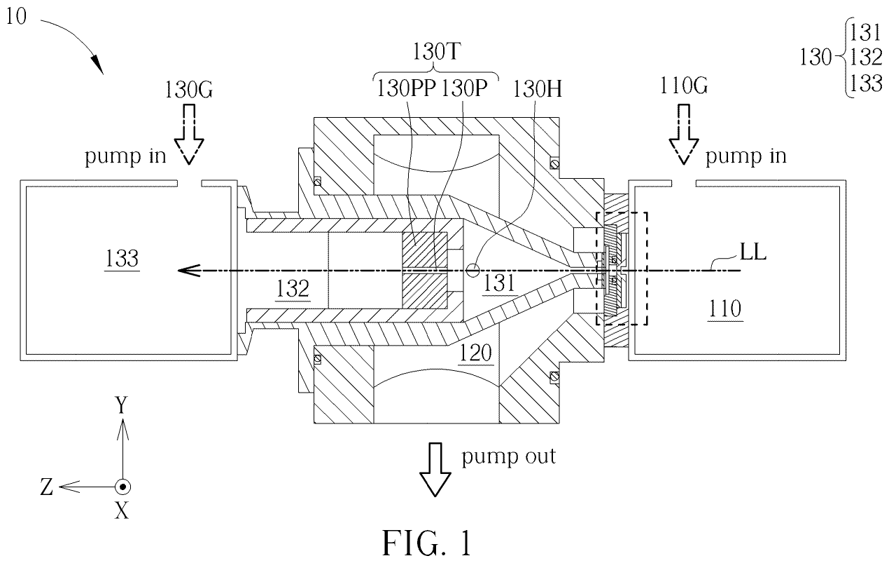

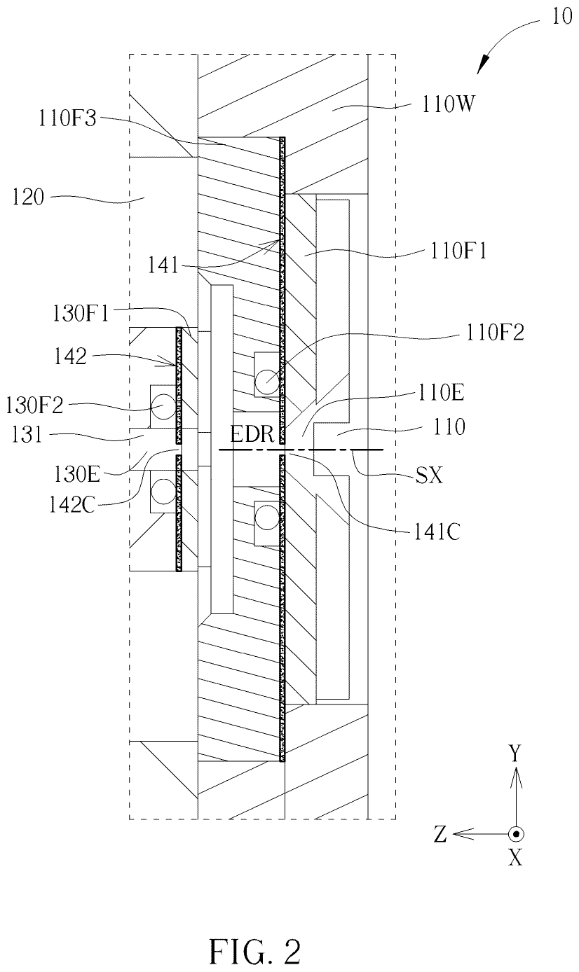

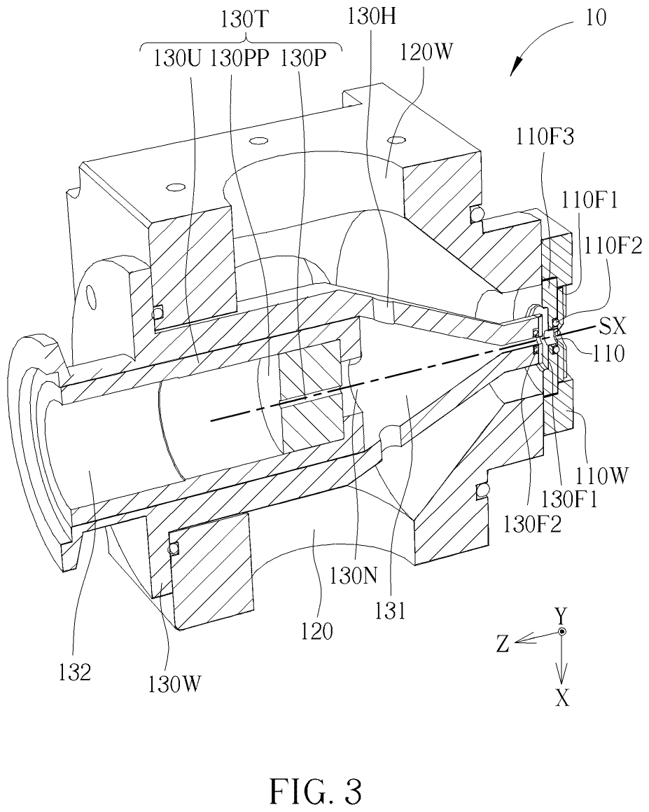

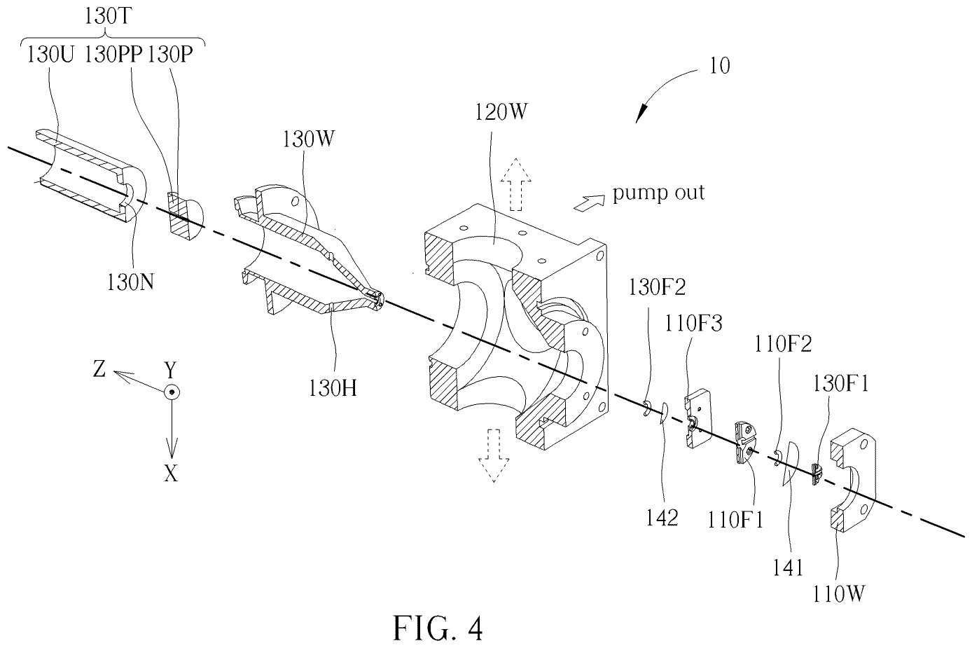

As shown in FIG. 1, the present invention proposes a device 10 (e.g., a pumping device, a radiation generator, an inspection device, a lithography light source, a plasma etching or chemical vapor deposition (CVD) machine, or a particle accelerator), which is able to maintain a pressure difference between different areas. FIG. 2 presents an enlarged schematic diagram of the device 10, enclosed in a dashed outline from FIG. 1. FIG. 4 depicts an exploded-view drawing of the device 10 shown in FIG. 3.

In terms of pressure, the device 10 may be divided into different areas such as chambers 110-130. The chamber 110, which connects to a tank holding a non-solid substance 110G, may experience the maximum pressure (e.g., 100-500 Torr). The pressure within the chamber 120 may be lower than the pressure within the chamber 110 or 130. The chamber 120 may be (nearly) evacuated, as indicated by a hollow arrow in FIG. 1, to maintain a low-pressure level or to create a vacuum (e.g., less than e⁻³ or 0.2 Torr but larger than 10⁻³ mbar). The chamber 130, which connects to a tank holding a non-solid substance 130G, has a different pressure (e.g., 2-50 Torr) compared to the chamber 110.

The device 10 may comprise films 141 and 142 to isolate these three pressure areas, as shown in FIG. 2. For example, the film 141, which is disposed near and between the chamber 120 and an open end 110E of the chamber 110, may comprise only one small orifice 141C to reduce the leakage of the non-solid substance 110G. Similarly, the film 142, which is disposed near and between the chamber 120 and an open end 130E of the chamber 130, may also comprise only one small orifice 142C to limit the leakage of the non-solid substance 130G. With the films 141 and 142 in place, each chamber may maintain its determined pressure, creating a pressure differential between the chambers without mutual interference.

However, there is a chance that the non-solid substance 130G might leak toward an area EDR between the two films 141 and 142. Particularly, the high pressure within the chamber 130 may push the non-solid substance 130G outward and drive the flow of the non-solid substance 130G toward or into the area EDR, leading to unstable flow. The higher the pressure in the chamber 130, the greater the potential for leakage may be. Such leakage may increase the pressure within the area EDR and degrade differential pumping.

To prevent the non-solid substance 130G from escaping into the area EDR through the open end 130E, the chamber 130 may comprise a channel structure 130T, which divides the chamber 130 into compartments 131 and 132 holding the non-solid substance 130G. A confiner 130PP may form a narrow passage 130P of the channel structure 130T. The length of the passage 130P is substantially greater than the width or diameter of its cross-section; the cross-section of the passage 130P is notably smaller than the cross-section of the compartment 131 or 132. This configuration of the channel structure 130T may restrict the non-solid substance 130G mostly to the compartment 132, such that the pressure in the compartment 132 (e.g., 2-20 Torr) is higher than that in the compartment 131 (e.g., less than 10 Torr). Even if the non-solid substances 110G and 130G do spread, the mixing of the non-solid substances 110G and 130G should occur in the compartment 131 instead of in the area EDR. In other words, while the non-solid substance 110G may traverse the area EDR, the design of the channel structure 130T prevents the non-solid substance 130G from leaking into the area EDR. Consequently, the device 10 may achieve an optimal level of differential pumping and provide excellent isolation that limits the flows of gases to adjacent areas.

Alternatively, to prevent the non-solid substance 130G from escaping into the area EDR through the open end 130E, the compartment 131 may comprise hole(s) (e.g., two holes 130H). The compartment 131 is connected to the chamber 120 not only through the open end 130E but also through the holes 130H. Consequently, the pressure of the compartment 131 may drop further. Besides, even if the pressure in the area EDR adjacent to the open end 130E is lower than 1 Torr, the non-solid substance 130G may flow more readily into the chamber 120 through the holes 130H rather than through the open end 130E, since the non-solid substance 130G encounters the holes 130H first. Additionally, even if the reduced pressure within the compartment 131 may cause the non-solid substance 110G to cross the area EDR or into the compartment 131, the mixing of the non-solid substances 110G and 130G may occur within the compartment 131 instead of in the area EDR. In others words, the holes 130H prevent the non-solid substance 130G from leaking to the area EDR through the open end 130E. The device 10 thus may achieve differential pumping with excellent isolation, limiting gas flow to neighboring areas.

In another aspect, the chambers 110 and 130 have different structures and are asymmetric because the chamber 130 may be designed to avoid leakage. Specifically, the non-solid substance 110G may leek to the area EDR or even to the compartment 131 when the pressure within the compartment 131 is low. However, the impact on photon absorption by the non-solid substance 110G is less than that by the non-solid substance 130G, making it acceptable. On the other hand, the chamber 130 has a distinct structure to prevent the non-solid substance 130G from escaping into the area EDR through the open end 130E. For example, a funnel section (e.g., 110F1) of the compartment 131, which substantially tapers toward the chamber 120, is enclosed by the chamber 120; on the other hand, a funnel section of the chamber 110, which substantially tapers toward the chamber 120, is only adjacent to the chamber 120. Alternatively, as set forth above, although the chamber 110 and the compartment 131 comprise the open ends 110E and 130E respectively, the compartment 131 further comprises the (bypass) hole 130H, which is oriented at an angle different/perpendicular from/to that of the open end 130E. Alternatively, as set forth above, the chamber 130 comprises an extended section (e.g., 130U or 130W) to accommodate the channel structure 130T.

The device 10 may uses one single vacuum pump to not only maintain the pressure in both the chambers 110 and 130 but also stabilize the flow of the non-solid substances 110G and 130G especially in the area EDR. Specifically, the chamber 120 (e.g., represented by the hollow arrow in FIG. 4) may be maintained at a low working pressure using a vacuum pump, a turbo-molecular pump, or a roughing pump, to facilitate differential pumping. On the other hand, no vacuum pump is directly connected to the chamber 110 or 130, thereby reducing costs. However, adding more pumps in the chamber 110 . . . or 130 (e.g., represented by dashed hollow arrows in FIG. 4) is also an option.

The device 10 may serve as a radiation generator. Within the chamber 110 or the area EDR, the device 10 may comprise optical components (e.g., separator(s), polarizer(s), mirror(s), or a lens) or medium(s) for frequency conversion to convert radiation LL (e.g., a laser beam) from infrared (IR) range to extreme ultraviolet (XUV) range. For example, nonlinear process/processes (e.g., second harmonic generation (SHG), third harmonic generation (THG), sum frequency generation (SFG), optical parametric amplification (OPA), spectral broadening, or other nonlinear effects) may occur within the chamber 110 or the area EDR because of the non-solid substance 110G. Although the non-solid substance 110G may be a nonlinear medium, the non-solid substance 130G may not be a nonlinear medium. Therefore, it is crucial to confine the non-solid substance (e.g., 110G or 130G) within its corresponding area (e.g., 110, 130, or EDR) without leakage.

When the device 10 functions as a radiation generator, the leakage of the non-solid substance 130G into the area EDR may diminish the intensity of the output radiation LL from the device 10. Specifically, the radiation LL may be focused or have a narrow/minimal beam width within the area EDR (referred to as an efficiency-determining region). Given that the radiation intensity is high in the area EDR, photon absorption within the area EDR could be significant (resulting in fewer photon counts) if the pressure within the area EDR is also elevated. For example, when the pressure of the non-solid substance 130G exceeds 2 Torr, which may increase the pressure within the area EDR, light emission efficiency may drop. Nonetheless, the device 10 prevents the leakage of the non-solid substance 130G into the area EDR to decrease the pressure within the area EDR, thereby increasing photon counts.

Contamination is another issue for differential pumping. Although the film 141 or 142 may isolate directly-connected chambers to create a pressure difference, the orifice 141C or 142C in the film 141 or 142 allows not only gas leakage but also the spread of contaminants. For example, during laser drilling, parts of the film 141 or 142 may become contaminants through radiation LL (e.g., laser or XUV light), thereby creating the orifice 141C or 142C. Alternatively, any component of the device may produce chips (e.g., particles from O-ring outgassing) after long-term use. These contaminants may damage the components of the device 10.

The material of the confiner 130PP (or an adaptor 130U) may be properly selected to reduce contaminants into the compartment 133. For example, if the film 141 or 142 is made of metal (e.g., copper) or magnetic material(s), the material of the confiner 130PP may be magnetic to attract these laser-generated contaminants. Alternatively, the material of the confiner 130PP may be sticky, particularly for capturing nonmagnetic, non-ionized contaminants. As a result, the device 10 intercepts the contaminants and avoids the contaminants from entering the compartment 133.

Alternatively, to reduce contaminants, the device 10 may optionally comprise a valve (e.g., 530V), especially when the confiner 130PP cannot attract contaminants. The valve (e.g., 530V) divides the chamber 130 into the compartment 132 and a compartment 133, which connects to a tank holding the non-solid substance 130G. During laser drilling (or maintenance), the valve (e.g., 530V) is closed to separate the compartments 132 from the compartments 133, thereby effectively blocking the contaminants. Besides, the chamber 120 may be maintained at a vacuum (e.g., using a vacuum pump) to draw contaminants into the chamber 120. As a result, the device 10 avoids the contaminants from entering the compartment 133. The valve (e.g., 530V) is opened after the contaminants are exhausted/intercepted (or after the maintenance is completed). Moreover, the non-solid substance (e.g., 110G or 130G) may be pumped into the corresponding chamber (e.g., 110 or 130) before the laser drilling (or maintenance).

When the device 10 operates as an inspection device or a lithography light source, these contaminants or chips may damage optical components or impair performance. Specifically, within the compartment 133, the device 10 may comprise an illuminator (e.g., optical components) to manipulate/emit the output radiation LL or inspect small defects/features on an object (e.g., a patterned feature of a wafer after/during development/etching, transistor(s), drain(s)/source(s), metal contact(s), a metal-zero (M0), or metal-one (M1) layer). Alternatively, mirror(s), lens/lenses, or other optical components may be disposed within the compartment 133. When the device 10 is set to emit output radiation LL, the valve (e.g., 530V) is open. Conversely, when the device 10 does not emit any output radiation, the valve (e.g., 530V) is closed; meanwhile, the contaminants, potentially heated by the high-power radiation LL (e.g., more than 50 mW) or moved along with the propagation of the high-power radiation LL, may be intercepted/removed. Since the contaminants may react with the radiation LL and compromise optical components if they propagate downstream, minimizing the contaminants within the compartment 133 helps protect the object or the optical components from contamination.

The following describes the detailed structure of the device 10. As shown in FIG. 3, the device 10 may comprise frames 110W-130W. The frame 130W forms a funnel section of the compartment 131, which is wide at one end and narrow at the other end, an extension section of the compartment 132, the diameter or wide of which may remain invariant or vary with length, and a step-like section for a valve (e.g., 530V) or fastener(s). The dimensions or angle of the funnel section may be related to (e.g., exceed) the radiation beam width or the radiation divergent angle. Similarly, the frame 120W forms a funnel section and a cross-shaped section, which enclose the cone-shaped compartment 131, the channel structure 130T, and part of the compartment 132.

As shown in FIG. 2, the device 10 may comprise fasteners 110F1-110F3 and 130F1-130F2. The fasteners 110F1-110F3 are configured to secure/release the film 141, which may be renewed during maintenance. Likewise, the fasteners 130F1 and 130F2 are configured to secure/release the film 142. The fastener 110F1 forms a funnel section of the chamber 110; the fastener 110F3 forms a funnel-like section for the area EDR of the chamber 120, which connects to the chambers 110 and 130. The size or angle of the funnel section may be related to (e.g., exceed) the radiation beam width or the radiation convergent angle. The distance of the area EDR between the films 141 and 142 is short (e.g., less than twice the Rayleigh length) especially when the orifices 141C-142C on the films 141-142 are small. The films 141-142 are thin especially when the orifices 141C-142C function as pinholes. The orifices 141C-142C may be the smallest compare to other holes, openings, or the channel structure 830T, which may all be related to (e.g., exceed) the radiation beam width.

As shown in FIG. 4, the device 10 may comprise the adaptor 130U. An opening 130N of the adaptor 130U is wider than the passage 130P of the confiner 130PP, such that the confiner 130PP and the adaptor 130U together constitute the channel structure 130T in a step-like shape.

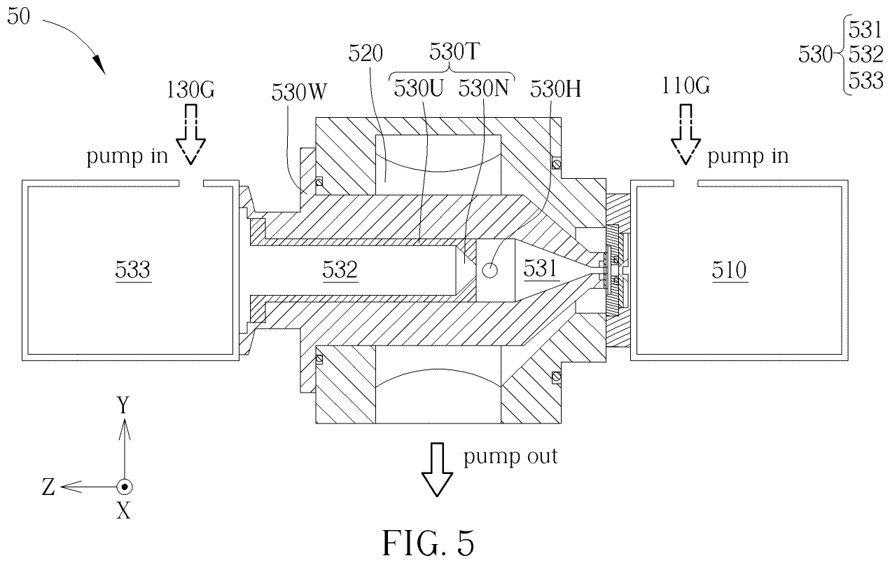

FIG. 5 is a schematic diagram of a device 50, which may be implemented using the device 10, according to an embodiment of the present invention.

As set forth above, the device 50 may comprise a valve 530V adjacent to the compartment 532. In other words, a channel structure 530T is disposed between the holes 530H and the valve 530V.

Compared to the chamber 130 shown in FIG. 1, the confiner 130PP is absent from a chamber 530 of the device 50. In other words, the narrow passage 130P may not be necessary. Alternatively, the device 50 does not require two separate pieces (i.e., 130PP and 130U) made of different materials.

Compared to the adaptor 130U shown in FIG. 1, an adaptor 530U of the device 50 substantially tapers from a compartment 532 toward a compartment 531, forming a nozzle 530N for the channel structure 530T. The small open end of the nozzle 530N prevents the non-solid substance 130G from leaking into the area EDR, thereby enhancing the differential pumping effect. The size of the open end or the angle of the nozzle 530N may be related to (e.g., greater than) the radiation beam width, the radiation divergent angle, or pressure difference.

Compared to the frame 130W shown in FIG. 4, a frame 530W of the device 50 is thicker. For example, the thickness of the frame 530W is substantially similar to the diameter of the compartment 532. The thickness of the frame 530W may allow the adaptor 530U to comprise a protrusion extending radially outward (i.e., from a symmetric axis SX toward a frame 530W).

Compared to the holes 130H located on a sloping wall of the compartment 131 shown in FIG. 1, two holes 530H of the device 50 are positioned on a tubular wall of a compartment 531. But the present invention is not limited thereto, and one or more hole(s) may be located on a flat wall of a compartment in another embodiment.

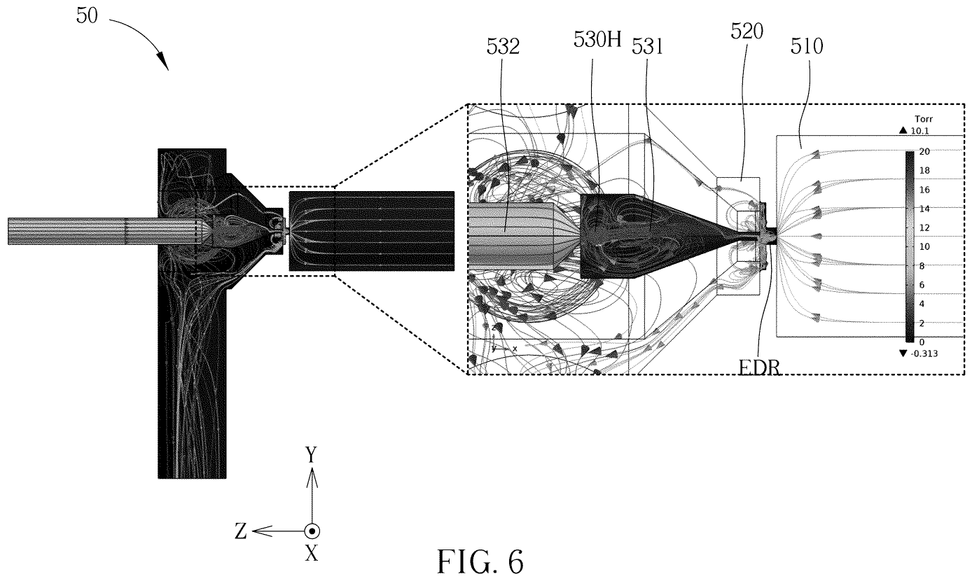

FIG. 6 illustrates a simulation of flow streams of the non-solid substances 110G and 130G in the device 50 shown in FIG. 5. In FIG. 6, arrows in a darker color represent the flow streams of the non-solid substance 130G, while arrows in a lighter color represent the flow streams of the non-solid substance 110G. Additionally, the gray scale decrease with pressure. The pressure of the non-solid substance 110G and the pressure of the non-solid substance 130G in FIG. 6 are approximately 143 Torr (represented in brightest white) and 10 Torr (represented in darkest black), respectively.

As shown in FIG. 6, the flow streams of the non-solid substance 130G are uniform (e.g., substantially parallel) in compartments 531-532. The non-solid substance 130G spreads into the compartment 531, and is drawn into the chamber 520 through the holes 530H without flowing into the area EDR. Similarly, the flow streams of the non-solid substance 110G are uniform (e.g., substantially parallel) in a chamber 510. The non-solid substance 110G spreads not only into the chamber 520 but also into the area EDR and the compartment 531. The non-solid substance 110G within the compartment 531 is sucked into the chamber 520 through the holes 530H. In other words, the device 50 remains effective in stabilizing the flow field and prevents the non-solid substance 130G from entering the area EDR.

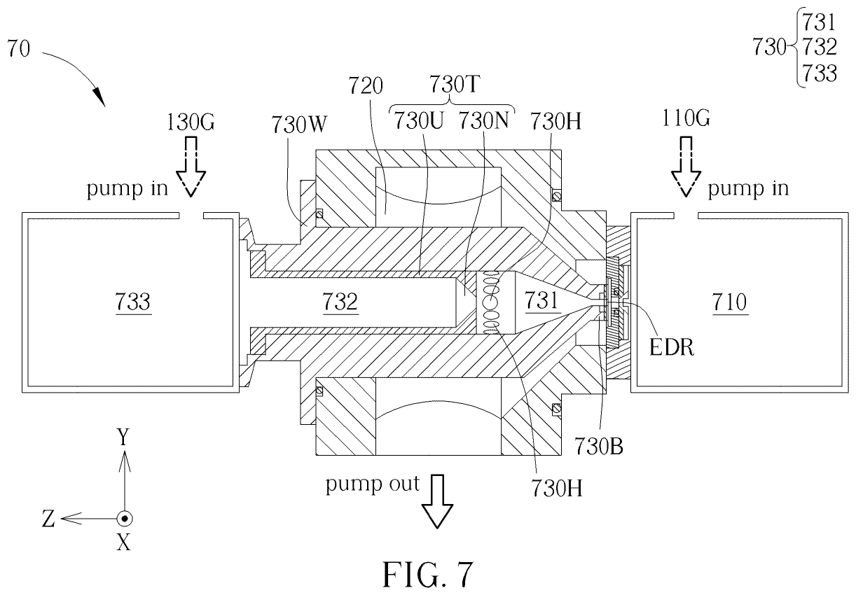

FIG. 7 is a schematic diagram of a device 70, which may be implemented using the device 10, according to an embodiment of the present invention. Compared to the two holes 530H of the compartment 531 shown in FIG. 5, a compartment 731 comprises more holes 730H (e.g., 16 holes). These holes 730H encircle the symmetric axis SX of an open end 530E, the compartment 731, 732, a channel structure 730T, a chamber 710, 720, or the area EDR.

In FIG. 7, the holes 730H are positioned closer to the channel structure 730T than the open end 730E. Alternatively, hole(s) may be arranged far from the inlet of the tank holding the non-solid substance 110G or 130G. Alternatively, hole(s) may be roughly equidistant from the channel structure 730T and the open end 730E. Alternatively, hole(s) may be positioned further from the channel structure 730T than the open end 730E. Hole(s) may not be located on an extension section 730B of the compartment 731 because hole(s) near the open end 730E may not effectively reduce the pressure of the compartment 731 and may allow the non-solid substance 130G to leak into the area EDR. The optimal placement of hole(s) depends on the pressure and the mass of the non-solid substance 130G.

In FIG. 7, the holes 730H encircle the symmetric axis SX. Alternatively, some holes of the compartment 531 may be arranged into one or more lines along the symmetric axis SX. Alternatively, holes of the compartment 531 may form two or more concentric circles around the symmetric axis SX.

In FIG. 7, the holes 730H feature the same size. Alternatively, some holes may vary in size. The area of a hole may exceed 50 square millimeters.

In FIG. 7, each hole is circular in shape. Alternatively, a hole may take the form of a triangle, quadrilateral, polygon, or irregular shape.

In FIG. 7, there are multiple holes 730H. Alternatively, the device may comprise only a single hole.

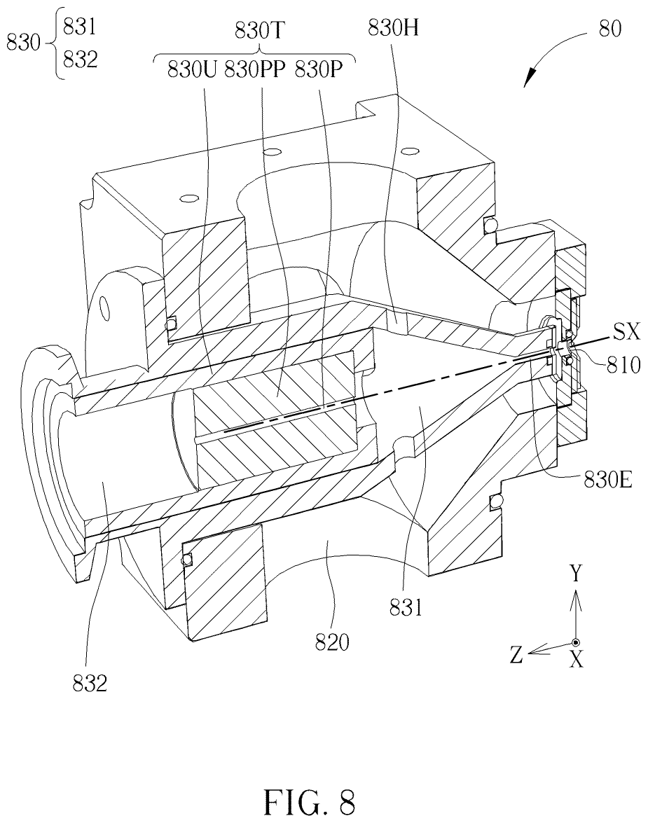

FIG. 8 is a schematic diagram of a device 80, which may be implemented using the device 10, according to an embodiment of the present invention. Compared to the passage 130P enclosed by the confiner 130PP shown in FIG. 1, a passage 830P enclosed by a confiner 830PP is longer.

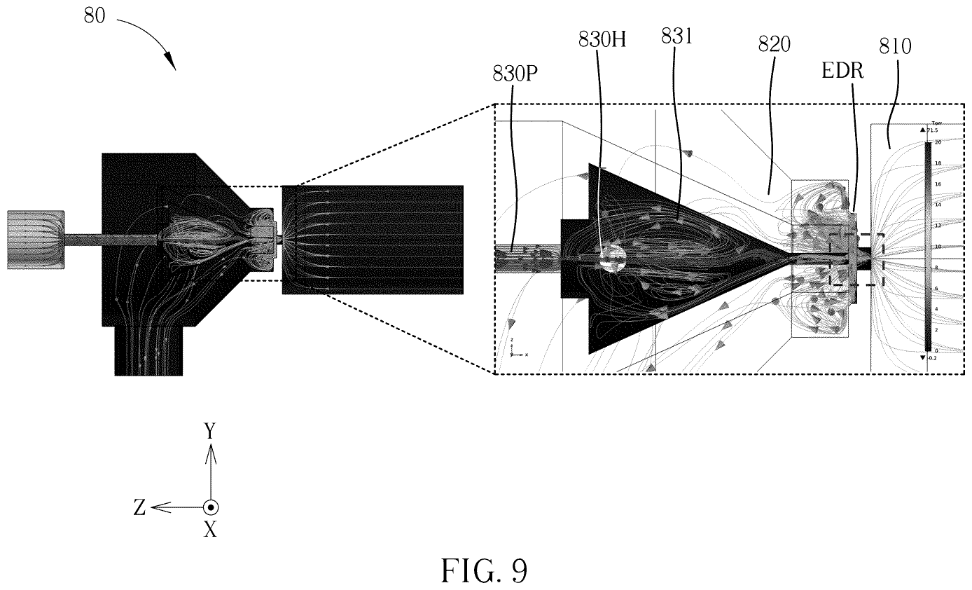

FIG. 9 illustrates a simulation of flow streams of the non-solid substances 110G and 130G in the device 80 shown in FIG. 8. The pressure of the non-solid substance 110G and the pressure of the non-solid substance 130G in FIG. 9 are approximately 143 Torr (represented in brightest white) and 10 Torr (represented in darkest black), respectively. As shown in FIG. 9, the flow streams of the non-solid substance 110G are uniform (e.g., substantially parallel) in a chamber 810. Similarly, the flow streams of the non-solid substance 130G are uniform (e.g., substantially parallel) in compartments 831-832 and a channel structure 830T without flowing into the area EDR. The non-solid substance 110G or 130G spreads into the compartment 831, and is drawn into the chamber 820 through the hole(s) 830H without entering the area EDR. In other words, the device 80 remains effective in stabilizing the flow field and prevents the non-solid substance 130G from entering the area EDR.

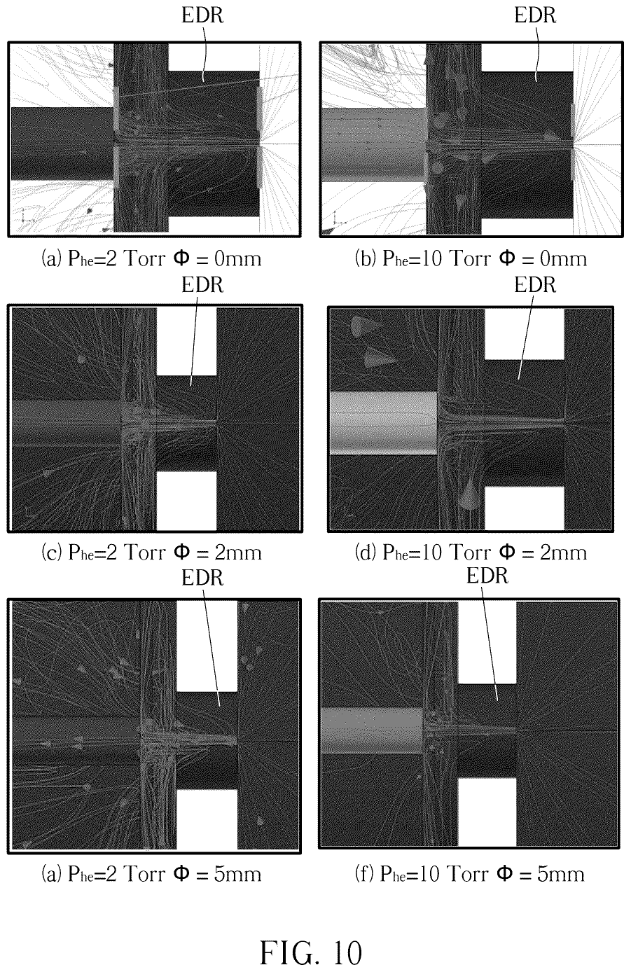

FIG. 10 illustrates a simulation of flow streams of the non-solid substances 110G and 130G under different pressure conditions. In FIGS. 10(a), (c), and (e), the pressure of the non-solid substance 130G is approximately 2 Torr, and the flow streams of the non-solid substance 110G are dominant. In FIGS. 10(b), (d), and (f), the pressure of the non-solid substance 130G is approximately 10 Torr. The higher pressure may push the non-solid substance 130G (i.e., the flow stream shown by arrows) toward an open end 830E (as shown in FIG. 10(d)) and even into the area EDR (as shown in FIG. 10(b)), causing flow instability or low XUV generation efficiency.

FIG. 10 also illustrates a simulation of flow streams of the non-solid substances 110G and 130G for different hole sizes. FIG. 10(f) may be an enlarged schematic diagram of the device 80, corresponding to a portion outlined by a thick dashed box in FIG. 9. In FIGS. 10(a) and (b), there is no hole in the cone-shaped compartment, and hence the hole diameter may be regarded as 0 millimeters. In FIGS. 10(c) and (d), the diameter of a hole is approximately 2 millimeters. Compared to FIG. 10(a), the two holes in the cone-shaped compartment shown in FIG. 10(c) provide an escape path for the non-solid substances 110G and 130G. As a result, the non-solid substance 110G not does not flow upward/downward, and the flow of the non-solid substance 130G moves along the symmetric/center axis SX. However, FIG. 10(c) or (d) exhibits limited effectiveness in reducing the flow instability. In FIGS. 10(e) and (f), the diameter of a hole (e.g., 830H) is approximately 5 millimeters. Compared to FIG. 10(d), the larger holes 830H in FIG. 10(f) effectively prevent the non-solid substance 130G from leaking to the area EDR through the open end 830E. However, increasing the hole size also leads to greater dissipation of the non-solid substance 130G. Therefore, the optimal size of hole(s) depends on the pressure, the pressure difference (e.g., between the compartments 131 and 132), or the overall structure.

The term “non-solid substance” inherently implies it is gaseous or plasma, and, for example, may comprise a gas, a gas mixture (e.g., the gas ratio of heavy atomic weight to light atomic weight ranging between 1:1 and 1:300), a plasma, a plasma mixture, or a combination thereof. For example, the non-solid substance 110G (e.g., configured to optimize phase matching for harmonic generation) may comprise a gas mixture of argon (Ar) and xenon (Xe), while the non-solid substance 130G (e.g., configured to enhance heat dissipation or reduce contamination) may comprise helium (He), low XUV absorption gas, or a gas of higher ionization energy.

The pressure in the compartments 133 affects the movement of particle(s) or the transmission of light. The higher the pressure in the compartments 133, the shorter the mean free path of particles in the compartments 133 may be. This may prevent particles (e.g., contaminants) from damaging optical/mechanical component(s) inside the compartments 133. Besides, the low pressure and low absorption property of the non-solid substance 130G ensure that an attenuation length (i.e., a propagation distance over which power drops to 1/e) exceeds 20 centimeters, such that the output radiation LL may propagate further without undue attenuation.

Materials are sophisticatedly selected. For example, the frames 110W-130W, for forming chambers 110-130 respectively, may be made of metal (e.g., steel) or high stiffness material(s), while the fasteners 110F2 and 130F2 (e.g., O-rings) may be made of rubber or other flexible material(s).

The film for differential pumping is sophisticatedly designed. The film 141 or 142 may be drilled using laser drilling or mechanical drilling. Alternatively, the plate structure of the film 141 or 142 may be replaced by a nozzle-like design.

The device is designed to avoid gas mixing, gas exchange, and component contamination in differential pumping. Gas mixing between chambers can disrupt the composition or pressure of the gases, compromising the reliability and reproducibility of experimental results due to altered experimental conditions. Gas exchange may diminish the efficiency of certain chamber-specific functionalities, such as phase matching optimization or heat dissipation, thereby degrading performance. Moreover, contaminants may diffuse from one chamber to another, increasing the risk of optical or mechanical component contamination.

To sum up, the present invention pertains to a dual-chamber vacuum system specifically designed to optimize the independence of the gas environments within each chamber, preventing gas exchange (e.g., gas leakage) between chambers. This design ensures the functional stability of each chamber and allows for meticulous control over experimental conditions.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A pumping device, comprising:
a first chamber;
a second chamber, located downstream of the first chamber; and
a third chamber, wherein the second chamber is connected between the first chamber and the third chamber;
wherein a channel structure divides the third chamber into a first compartment and a second compartment;
wherein the first compartment is enclosed between the second chamber and the second compartment;
wherein the first compartment and the second chamber are connected through an open end and at least one hole of the first compartment;
wherein the open end and the at least one hole are oriented at different angles;
wherein pressure within the second chamber is lower than pressure within the first chamber, pressure within the first compartment, and pressure within the second compartment.

2. The pumping device of claim 1, wherein the channel structure comprises a passage, with a cross-section smaller than a first cross-section of the first compartment and a second cross-section of the second compartment, wherein a length of the passage is substantially greater than a width or a diameter of the cross-section.

3. The pumping device of claim 1, wherein the channel structure comprises a nozzle, which substantially tapers from the second compartment toward the first compartment.

4. The pumping device of claim 1,
wherein the at least one hole is positioned closer to the channel structure than the open end;
wherein one of the at least one hole is located on a sloping wall, a flat wall, or a tubular wall of the first compartment.

5. The pumping device of claim 1, wherein the at least one hole encircles a symmetric axis of the open end.

6. The pumping device of claim 1, further comprising:
a valve, disposed adjacent to the second compartment; and
a first film, disposed between the first chamber and the second chamber;
wherein the channel structure is disposed between the at least one hole and the valve;
wherein the valve is closed when the first film is drilled by radiation;
wherein the valve is opened after the first film is drilled by the radiation.

7. The pumping device of claim 6, further comprising:
a second film, disposed between the second chamber and the first compartment;
wherein the minimum beam width of the radiation is located between the first film and the second film;
wherein a width or a diameter of the open end or the channel structure is greater than corresponding beam widths of the radiation.

8. The pumping device of claim 1,
wherein a second film of the pumping device is drilled using radiation to create an orifice on the second film and form contaminants;
wherein the contaminants are attracted by a confiner of the channel structure or drawn into the second chamber; wherein the confiner comprises magnetic material.

9. The pumping device of claim 1,
wherein the first chamber holds a first non-solid substance for nonlinear effect;
wherein the second compartment holds a second non-solid substance with low radiation absorption;
wherein the pressure within the first chamber is higher than the pressure within the second compartment;
wherein no vacuum pump is directly connected to the first chamber or the second compartment.

10. The pumping device of claim 1,
wherein the first chamber comprises a funnel section substantially tapers toward the second chamber; or
wherein the second chamber or the first compartment comprises a funnel section substantially tapers toward the first chamber.

11. A pumping method for a pumping device, wherein the pumping device comprises a first chamber, a second chamber, and a third chamber, the second chamber is connected between the first chamber and the third chamber, and the pumping method comprising:
maintaining pressure within the second chamber lower than pressure within the first chamber, pressure within a first compartment of the third chamber, and pressure within a second compartment of the third chamber; and
maintaining a connection between the first compartment and the second chamber through an open end and at least one hole of the first compartment;
wherein a channel structure divides the third chamber into the first compartment and the second compartment;
wherein the first compartment is enclosed between the second chamber and the second compartment;
wherein the open end and the at least one hole are oriented at different angles.

12. The pumping method of claim 11, further comprising:
closing a valve of the pumping device when a first film of the pumping device is drilled by radiation; or
opening the valve after the first film is drilled by the radiation;
wherein the first film is disposed between the first chamber and the second chamber;
wherein the valve is disposed adjacent to the second compartment;
wherein the channel structure is disposed between the at least one hole and the valve.

13. The pumping method of claim 11,
wherein the pumping device further comprises a second film, disposed between the second chamber and the first compartment;
wherein the minimum beam width of the radiation is located between the first film and the second film;
wherein a width or a diameter of the open end or the channel structure is greater than corresponding beam widths of the radiation.

14. The pumping method of claim 11, further comprising:
drilling a second film of the pumping device using radiation to create an orifice on the second film and form contaminants;
wherein the contaminants are attracted by a confiner of the channel structure or drawn into the second chamber;
wherein the confiner comprises magnetic material.

15. The pumping method of claim 11, further comprising:
filling the first chamber with a first non-solid substance for nonlinear effect;
filling the second compartment with holds a second non-solid substance with low radiation absorption;
wherein the pressure within the first chamber is higher than the pressure within the second compartment;
wherein no vacuum pump is directly connected to the first chamber or the second compartment.

16. A radiation generator, comprising:
a first chamber;
a second chamber, connected to the first chamber via a first open end; and
a third chamber, connected to the second chamber via a second open end;
wherein input radiation is converted at least into extreme ultraviolet (XUV) radiation via at least one nonlinear process in the first chamber or between the first open end and the second open end;
wherein a channel structure divides the third chamber into a first compartment and a second compartment;
wherein the first compartment and the second chamber are connected through an open end and at least one hole of the first compartment;
wherein the open end and the at least one hole are oriented at different angles.

17. The radiation generator of claim 16, further comprising:
a valve, disposed adjacent to the second compartment; and
a first film, disposed adjacent to the first open end;
wherein the channel structure is disposed between the at least one hole and the valve;
wherein the valve is opened after the first film is drilled by the input radiation.

18. The radiation generator of claim 17, further comprising:
a second film, disposed adjacent to the second open end
wherein the minimum beam width of the extreme ultraviolet radiation is located between the first film and the second film;
wherein a width or a diameter of the open end or the channel structure is greater than corresponding beam widths of the extreme ultraviolet radiation.

19. The radiation generator of claim 16,
wherein a second film of the radiation generator is drilled using the input radiation to create an orifice on the second film and form contaminants;
wherein the contaminants are attracted by a confiner of the channel structure or drawn into the second chamber;
wherein the confiner comprises magnetic material.

20. The radiation generator of claim 16, wherein the channel structure comprises:
a passage, with a cross-section smaller than a first cross-section of the first compartment and a second cross-section of the second compartment, wherein a length of the passage is substantially greater than a width or a diameter of the cross-section; or
a nozzle, which substantially tapers from the second compartment toward the first compartment.
